(19) United States
(12) Patent Application Publication
(10) Pub. No.: US 2026/0064101 A1
(43) Pub. Date: Mar. 5, 2026

(54) INTERFACE MODULATION AND BUTTON FUNCTION REPLICATION

(71) Applicant: INTERNATIONAL BUSINESS MACHINES CORPORATION, Armonk, NY (US)

(72) Inventors: Zachary Augustus Silverstein, Georgetown, TX (US); Logan Bailey, Atlanta, GA (US); Hamid Majdabadi, OTTAWA (CA); Suman Patra, KOLKATA (IN)

(21) Appl. No.: 18/816,325

(22) Filed: Aug. 27, 2024

(51) Int. Cl. G05B 19/4099; G06F 30/17

(52) U.S. Cl. CPC G05B 19/4099; G06F 30/17; G05B 2219/49023

(57) ABSTRACT

Methods and systems for interface modulation include recording interactions by a device operator with an original interface of the device. A function of the original interface is determined using a trained predictive model that receives sequences of the interactions. A three-dimensional (3D) design is generated for a new interface that includes an indicator of the function. A new interface is fabricated according to the 3D design using an additive manufacturing process.

### BACKGROUND

The present invention generally relates to additive manufacturing and, more particularly, to customization of industrial machinery.

Some user interfaces may include physical buttons that accept inputs from users. For example, anything from complex industrial manufacturing tools to single-purpose internet-of-things (IoT) devices may have physical buttons to trigger a variety of functions. These buttons may be generic in the sense that they include no physical markings or other structure to indicate the function that they are associated with. While operators who are very familiar with the device, or who have access to the device’s manual, may be able to operate the device without such indicators, a new operator will have no way to know what will happen when a given generic button is pressed.

### SUMMARY

A method for interface modulation include recording interactions by a device operator with an original interface of the device. A function of the original interface is determined using a trained predictive model that receives sequences of the interactions. A three-dimensional (3D) design is generated for a new interface that includes an indicator of the function. A new interface is fabricated according to the 3D design using an additive manufacturing process.

A computer program product includes one or more computer-readable storage media and program instructions stored on the one or more storage media to perform operations. The operations include recording interactions by a device operator with an original interface of the device, determining a function of the original interface using a trained predictive model that receives sequences of the interactions, generating a 3D design for a new interface that includes an indicator of the function, and triggering fabrication of a new interface according to the 3D design using an additive manufacturing process.

A computer system includes a processor set, one or more computer-readable storage media, and program instructions stored on the one or more storage media to cause the processor set to perform operations. The operations include recording interactions by a device operator with an original interface of the device, determining a function of the original interface using a trained predictive model that receives sequences of the interactions, generating a 3D design for a new interface that includes an indicator of the function, and triggering fabrication of a new interface according to the 3D design using an additive manufacturing process.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a diagram showing modulation of an interface for a physical device, in accordance with an embodiment of the present invention;

FIG. 2 is a block/flow diagram of a method for modulating the interface of a physical device, in accordance with an embodiment of the present invention;

FIG. 3 is a block/flow diagram of a method for identifying the functions associated with a user interface of a device, in accordance with an embodiment of the present invention;

FIG. 4 is a block/flow diagram of a method for generating a new three-dimensional (3D) design for an interface, in accordance with an embodiment of the present invention;

FIG. 5 is a diagram illustrating how a new interface can be used to represent the function of an original interface, in accordance with an embodiment of the present invention;

FIG. 6 is a block diagram illustrating a computer environment that can perform interface modulation and button function replication, in accordance with an embodiment of the present invention;

FIG. 7 is a diagram of an exemplary neural network architecture that can be used in a predictive model, in accordance with an embodiment of the present invention; and

FIG. 8 is a diagram of an exemplary deep neural network architecture that can be used in a predictive model, in accordance with an embodiment of the present invention.

### DETAILED DESCRIPTION

The user interfaces of physical devices can be modulated by replacing generic buttons with buttons that better communicate their own function. For example, a generic button may be replaced with one that has a design or label printed on it, which can help a new operator understand what that button does. The new button may be fabricated using additive manufacturing, such as by a three-dimensional (3D) printing process, so that the physical shape of the button includes a 3D rendering of the label.

In some cases, the function of the generic button may not be known a priori. This may occur when the device in question is old or when its operating manual has been lost. The operator of the machine may not know themselves what each button does, but may instead operate the machine by rote, having memorized a sequence of button presses to achieve their goal. In such a case, the function of the button needs to be discovered before a suitable replacement button can be created. A machine learning system may be used to automatically discover the function of a button based on a history of operator interactions, using patterns of inputs to assign a likely function.

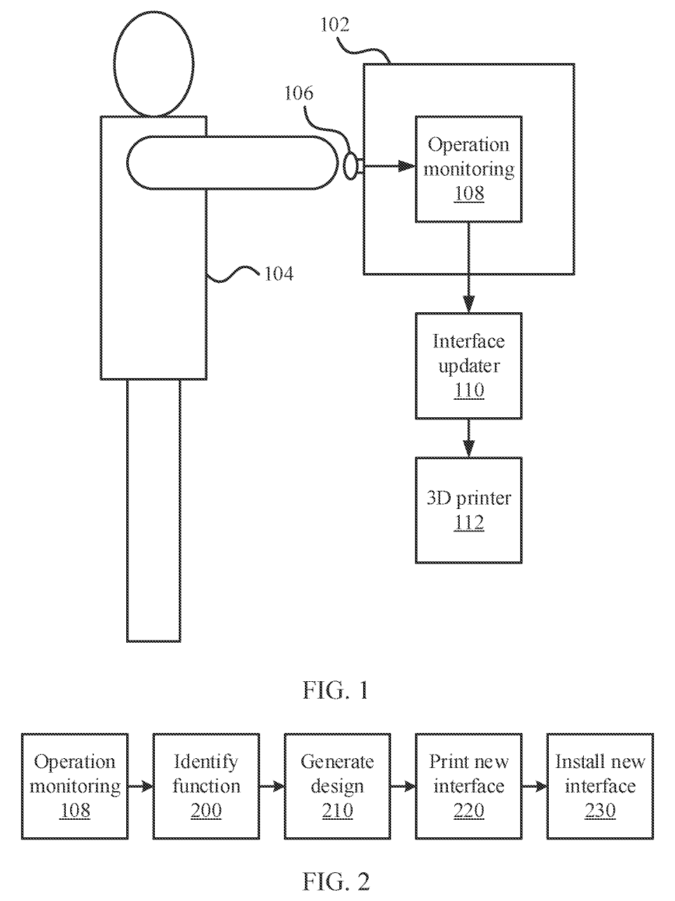

Referring now to FIG. 1, an exemplary user interface is shown. A device 102 is shown with an operator 104. The operator 104 interacts with the machine by an interface 106, in this case shown as a physical button. While generic actuatable buttons are specifically contemplated, it should be understood that any physical interface may be used instead, such as a lever, switch, knob, dial, joystick, trackball, keypad, or pedal. In some cases, the interface 106 may have a generic (e.g., blank) operator-facing surface or may have an indicator that does not reflect the function that the interface 106 is associated with. In some cases, the interface 106 may have once had a label or indicator that has, through use or wear-and-tear, been removed or obliterated. In some cases, the interface 106 may have multiple discrete physical controls, such as multiple buttons, each with a different respective function in the device 102.

During use, operation monitoring 108 may register interactions between the operator 104 and the interface 106. The operation monitoring 108 may be accomplished by sensors that are integrated with the device 102 or by external sensors. In some cases, a video camera may be used to monitor the interface 106, so that actions of the operator 104 may be captured and identified. For example, operation monitoring 108 may record a time at which the operator 104 interacts with the interface 106, including an identification of the action performed (e.g., pressing a button or flipping a switch) and a timestamp at which the action is performed. In some cases operation monitoring 108 may make use of logs that are generated by the device 102, with information relevant to the activation of the interface 106 being extracted therefrom.

Operation monitoring 108 can thereby create a record of the operation of the device 102, identifying sequences of interactions with the interface 106. In some cases, responses by the device 102 may also be recorded and correlated with the recorded actions. For example, if the device 102 generates some visible change or output, for example by changing the status of an indicator (e.g., activating or extinguishing a lighted component), this fact may be recorded by operation monitoring 108.

The records of the user’s interaction with the interface 106 are sent to interface updated 110. The interface updater 110 generates a 3D design for a new interface, which is physically compatible with the original interface 106 but that includes an indication of the function of the interface 106. A 3D printer 112 is then used to fabricate the new interface, which can be used to replace the original interface 106.

Referring now to FIG. 2, a process for modulating the interface of a device is shown. As described above, block 108 performs operation monitoring to collect sequences of operations performed on the device 102. Block 200 identifies the function of the interface 106. The function identification 200 may, as described below, be performed using a digital twin and a machine learning system that tracks the behavior of the device 102 in response to actions and determines what function(s) are associated with particular actions performed on the interface 106.

Once a function of the interface 106 has been identified, block 210 generates a new design for the interface 106. The new design may include a label or other physical signifier of the identified function of the interface 106. For example, if the interface 106 is a button, and its function has been identified as pausing operation of the device, then the new design may be a button that includes an embossed or raised symbol to indicate the “pause” function. Block 220 then prints a replacement interface using the new design, which can be used to replace a generic component of the interface 106. The original interface 106 may be removed and the replacement interface may be installed.

Although 3D printing is specifically contemplated, printing the new interface 220 may include any appropriate type of manufacturing. Exemplary types of additive manufacturing that can be used include fuse deposition modeling (FDM), vat photopolymerization, and powder bed fusion. The new interface is produced to be compatible with the original interface 106.

Block 230 installs the new interface. In some cases, block 230 may remove original interface 106 and may replace it with the new interface. In some cases, the new interface may include a cover that couples to the original interface 106, in which case block 230 attaches the new interface to the original interface.

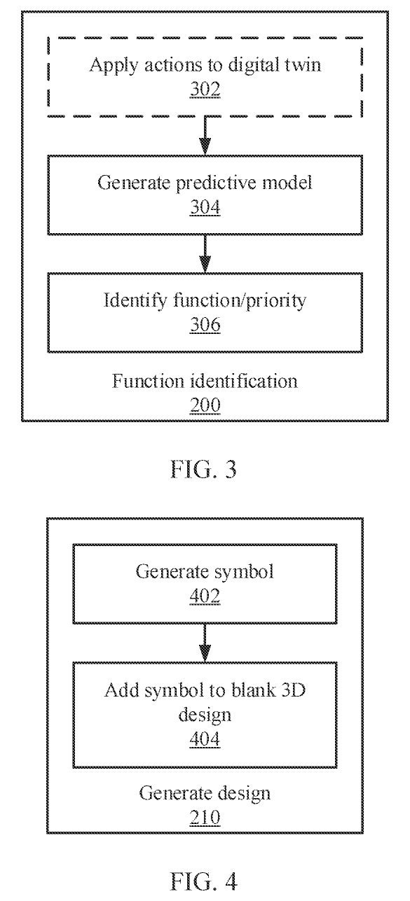

Referring now to FIG. 3, additional detail is provided on the function identification 200. Information from the operation monitoring 108 is used to create a correspondence between operator actions and the behavior of the device 102. In some cases, the behavior of the device may be recorded directly by operation monitoring 108. In some cases, the actions recorded in the operation monitoring 108 may be applied to a digital twin of the device in block 302 and the actions performed by the digital twin may be recorded. In some cases, operation monitoring 108 may directly employ the digital twin, with the operator 104 interacting with the digital twin instead of with the physical device 102.

Block 304 trains a machine learning model to perform function prediction. For example, a long-short term memory (LSTM) neural network may be used to process sequences of actions to predict frequent interactions and patterns. The trained predictive model associates the interface 106 with a priority/frequency or functionality. In some cases the sequence may indicate a particular function, and in some cases the interface 106 may be a part of a consistent sequence of inputs. For example, if a sequence of four buttons is always operated in the same order, then the function of the individual buttons may be difficult to ascertain, but the position of each button in the sequence may be identified. Block 306 then uses the actions of the operator 104 to identify the function or priority of the interface 106.

The training data for block 304 may come from log files from the device 102 or a similar device. For example, in an internet of things device, logs and data exhaust may be collected from multiple similar devices. Log analysis may be used to organize the log data, creating a correspondence between the trigger of an interface 106 and a function of the device 102. Visual data from cameras may further be used to identify button interactions and the frequency with which they are used. The data may then be structured as time series information, represented as sequences of events and associated time stamps for input to the LSTM model. For example, training data may include a sequence of interface activation events, associated functions for each activation, timestamps for each activation, and any additional information such as code comments, on-screen component information, and variable names that may be available.

In some cases, the training data may be collected from multiple devices that have similar functions and/or interfaces. A general model may thereby be trained, with fine-tuning being performed using additional data extracted from the specific device 102 being used. For example, the general model may be trained based on multiple devices of the same make and model that are used in different contexts to capture a general association between interfaces and their functions, while the fine-tuning may use data from a single device to capture the semantics of how it is used in its unique context.

The model may be trained to generate a prediction of the most frequent interface activations (e.g., button touches). For example, this may be represented as a set of probabilities or an ordered list of buttons by likelihood of activation. The predictions may also, or alternatively, include predictions of the most frequent associated functionality, which may be in the form of a text description or of categorical labels that represent the different functions. The output of the model is used to generate a simple order and pattern of repetition for interface activations. This output may be used to, for example, create a graphical representation of the interfaces, feed into natural language understanding model to process the expected functionality, and generate an input for the design generation 210 to create relevant icons or logos that represent the functionality.

Referring now to FIG. 4, additional detail is provided on generating the design 210. Block 402 generates a symbol based on the identified function of the interface 106. For example, block 402 may select from a library of pre-generated images that relate to different identified functions. In some cases, block 402 may use an image generation system based on a large language model (LLM) to generate an icon or symbol using an appropriate natural language prompt. In some cases, block 402 may use a generative adversarial network (GAN), trained on a set of existing images, to generate a new symbol. In some cases, where the output of block 200 is a number corresponding to a priority of the interface 106, block 402 may generate a corresponding number to indicate the place of the interface 106 in a sequence.

The use of a GAN may be more effective than searching a database of labeled icons/symbols when, for example, the functionality is uncommon or when a customized or unique icon is needed to represent the function. The GAN can create a novel graphic representation for a function that has not been encountered before. The GAN can furthermore adapt to changing design trends and user preferences more easily than a fixed database, which will by its nature be dominated by historical graphics. Furthermore, the GAN can be used to maintain a specific style or design language across various icons to generate a consistent graphical appearance across its designs. For systems with a large number of potential functions, the GAN can generate icons on demand without the need for an extensive pre-existing database.

The GAN may be trained using a two-part process. A generator model may be used to create images (e.g., icons or logos) based on text descriptions of a function, and a discriminator model may be trained to distinguish between real (pre-existing) icons and generated ones. The discriminator model is used to adjust the generator’s output, ensuring that generated images are realistic. Training data for the GAN may come from, e.g., existing icon/logo databases that provide examples of good icons for various functions, text descriptions of functions that are paired with icons to teach the relationship between function and visual representation, design guidelines and brand identity documents to inform the style and characteristics of the generated icons, user feedback if available, and code comments and other programmed text elements to provide context about the functionality that the icon should represent. The GAN’s training data may be preprocessed to create associations between text descriptions and corresponding images. This creates a diverse dataset covering a wide range of functions and visual styles, so that the GAN can generate appropriate icons.

Block 404 then adds the output of block 402 to an appropriate 3D design. For example, a blank may be drawn from a library of pre-designed 3D structures that are compatible with the interface 106. In some cases, the blank may be a generic button that is structurally compatible with, and can be swapped for, the original interface 106. Block 404 adds the generated symbol to a surface of the 3D design to combine them into a design for a single 3D structure that can replace the interface 106 and that includes an appropriate symbol indicating the function of the interface 106.

In some cases, the symbol generation 402 may be tailored to a particular user for the device 102. For example, the user may use a particular button or set of buttons most frequently, and the user’s preferred buttons may be identified as a personalized set. The symbol may provide visual emphasis, such as with bold text, coloring, or special texturing, to indicate its preferred status.

The blank 3D design may be selected to match the structure of the original interface 106. This may include the use of a digital twin that includes detailed information about the specifications of the device 102, including physical dimensions of the original interface 106 and button layouts. The structure of the blank 3D design may be specified in, e.g., standard tessellation language, which may be used for 3D printing to define the geometry of an object. The blank 3D design takes the same basic shape of the original interface (e.g., a circular button) and imposes the generated symbol on it.

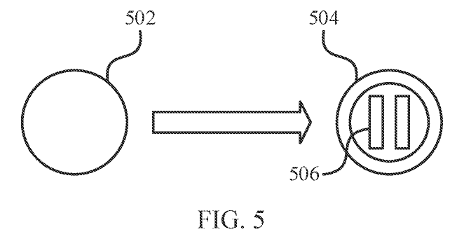

Referring now to FIG. 5, an example of how the interface 106 may be changed is shown. The original interface 502 is shown on the left as a generic button. While the button may have any color or shape, it is specifically contemplated that the button lacks a clear indication of the function it triggers within the device 102. In this example, pressing the button 502 causes the operation of the device 102 to pause, and pressing it again causes the operation of the device 102 to resume.

The original interface 502 may be replaced with a new interface 504, with a design that is automatically selected to match the identified function. In this case, the new interface 504 incorporates an icon 506 that denotes a “pause” function. In some cases, the icon 506 may be incorporated in the new interface 504 in a raised or embossed fashion, so that it protrudes from the body of the new interface 504. In some cases, the icon 506 may be printed on the surface of the new interface 504 to provide a visual indicator of the function.

The new interface 504 may include a connector or other attachment mechanism that matches an attachment mechanism of the original interface 502. For example, if the original interface 502 is threaded, then the new interface 504 may be similarly threaded so that serves as a direct replacement. During the generation of the design in block 210, the blank 3D design is selected in accordance with the physical dimensions and structural relationships of the original interface 502.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 600 contains an example of an environment for the execution of at least some of the computer code involved in performing the inventive methods, such as interface modulation and button function replication 619. In addition to block 619, computing environment 600 includes, for example, computer 601, wide area network (WAN) 602, end user device (EUD) 603, remote server 604, public cloud 605, and private cloud 606. In this embodiment, computer 601 includes processor set 610 (including processing circuitry 620 and cache 621), communication fabric 611, volatile memory 612, persistent storage 613 (including operating system 622 and block 619, as identified above), peripheral device set 614 (including user interface (UI) device set 623, storage 624, and Internet of Things (IoT) sensor set 625), and network module 615. Remote server 604 includes remote database 630. Public cloud 605 includes gateway 640, cloud orchestration module 641, host physical machine set 642, virtual machine set 643, and container set 644.

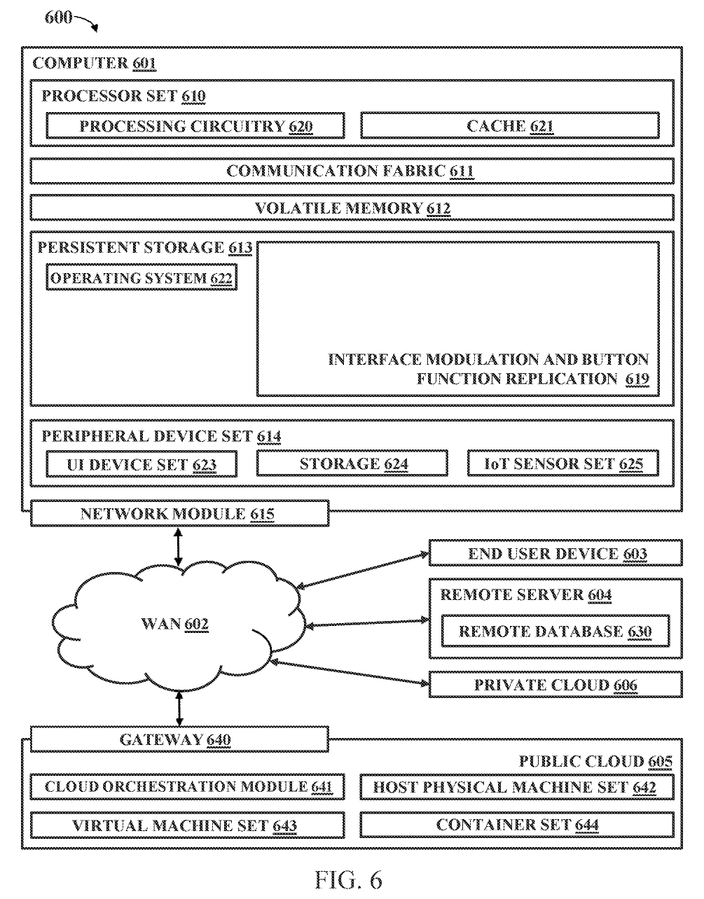

COMPUTER 601 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 630. As is well understood in the art of computer technology, and depending upon the technology, performance of a computer-implemented method may be distributed among multiple computers and/or between multiple locations. On the other hand, in this presentation of computing environment 600, detailed discussion is focused on a single computer, specifically computer 601, to keep the presentation as simple as possible. Computer 601 may be located in a cloud, even though it is not shown in a cloud in FIG. 6. On the other hand, computer 601 is not required to be in a cloud except to any extent as may be affirmatively indicated.

PROCESSOR SET 610 includes one, or more, computer processors of any type now known or to be developed in the future. Processing circuitry 620 may be distributed over multiple packages, for example, multiple, coordinated integrated circuit chips. Processing circuitry 620 may implement multiple processor threads and/or multiple processor cores. Cache 621 is memory that is located in the processor chip package(s) and is typically used for data or code that should be available for rapid access by the threads or cores running on processor set 610. Cache memories are typically organized into multiple levels depending upon relative proximity to the processing circuitry. Alternatively, some, or all, of the cache for the processor set may be located “off chip.” In some computing environments, processor set 610 may be designed for working with qubits and performing quantum computing.

Computer readable program instructions are typically loaded onto computer 601 to cause a series of operational steps to be performed by processor set 610 of computer 601 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 621 and the other storage media discussed below. The program instructions, and associated data, are accessed by processor set 610 to control and direct performance of the inventive methods. In computing environment 600, at least some of the instructions for performing the inventive methods may be stored in block 619 in persistent storage 613.

COMMUNICATION FABRIC 611 is the signal conduction path that allows the various components of computer 601 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

VOLATILE MEMORY 612 is any type of volatile memory now known or to be developed in the future. Examples include dynamic type random access memory (RAM) or static type RAM. Typically, volatile memory 612 is characterized by random access, but this is not required unless affirmatively indicated. In computer 601, the volatile memory 612 is located in a single package and is internal to computer 601, but, alternatively or additionally, the volatile memory may be distributed over multiple packages and/or located externally with respect to computer 601.

PERSISTENT STORAGE 613 is any form of non-volatile storage for computers that is now known or to be developed in the future. The non-volatility of this storage means that the stored data is maintained regardless of whether power is being supplied to computer 601 and/or directly to persistent storage 613. Persistent storage 613 may be a read only memory (ROM), but typically at least a portion of the persistent storage allows writing of data, deletion of data and re-writing of data. Some familiar forms of persistent storage include magnetic disks and solid state storage devices. Operating system 622 may take several forms, such as various known proprietary operating systems or open source Portable Operating System Interface-type operating systems that employ a kernel. The code included in block 619 typically includes at least some of the computer code involved in performing the inventive methods.

PERIPHERAL DEVICE SET 614 includes the set of peripheral devices of computer 601. Data communication connections between the peripheral devices and the other components of computer 601 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 623 may include components such as a display screen, speaker, microphone, wearable devices (such as goggles and smart watches), keyboard, mouse, printer, touchpad, game controllers, and haptic devices. Storage 624 is external storage, such as an external hard drive, or insertable storage, such as an SD card. Storage 624 may be persistent and/or volatile. In some embodiments, storage 624 may take the form of a quantum computing storage device for storing data in the form of qubits. In embodiments where computer 601 is required to have a large amount of storage (for example, where computer 601 locally stores and manages a large database) then this storage may be provided by peripheral storage devices designed for storing very large amounts of data, such as a storage area network (SAN) that is shared by multiple, geographically distributed computers. IoT sensor set 625 is made up of sensors that can be used in Internet of Things applications. For example, one sensor may be a thermometer and another sensor may be a motion detector.

NETWORK MODULE 615 is the collection of computer software, hardware, and firmware that allows computer 601 to communicate with other computers through WAN 602. Network module 615 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 615 are performed on the same physical hardware device. In other embodiments (for example, embodiments that utilize software-defined networking (SDN)), the control functions and the forwarding functions of network module 615 are performed on physically separate devices, such that the control functions manage several different network hardware devices. Computer readable program instructions for performing the inventive methods can typically be downloaded to computer 601 from an external computer or external storage device through a network adapter card or network interface included in network module 615. WAN 602 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 603 is any computer system that is used and controlled by an end user (for example, a customer of an enterprise that operates computer 601), and may take any of the forms discussed above in connection with computer 601. EUD 603 typically receives helpful and useful data from the operations of computer 601. For example, in a hypothetical case where computer 601 is designed to provide a recommendation to an end user, this recommendation would typically be communicated from network module 615 of computer 601 through WAN 602 to EUD 603. In this way, EUD 603 can display, or otherwise present, the recommendation to an end user. In some embodiments, EUD 603 may be a client device, such as thin client, heavy client, mainframe computer, desktop computer and so on.

REMOTE SERVER 604 is any computer system that serves at least some data and/or functionality to computer 601. Remote server 604 may be controlled and used by the same entity that operates computer 601. Remote server 604 represents the machine(s) that collect and store helpful and useful data for use by other computers, such as computer 601. For example, in a hypothetical case where computer 601 is designed and programmed to provide a recommendation based on historical data, then this historical data may be provided to computer 601 from remote database 630 of remote server 604.

PUBLIC CLOUD 605 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 605 is performed by the computer hardware and/or software of cloud orchestration module 641. The computing resources provided by public cloud 605 are typically implemented by virtual computing environments that run on various computers making up the computers of host physical machine set 642, which is the universe of physical computers in and/or available to public cloud 605. The virtual computing environments (VCEs) typically take the form of virtual machines from virtual machine set 643 and/or containers from container set 644. It is understood that these VCEs may be stored as images and may be transferred among and between the various physical machine hosts, either as images or after instantiation of the VCE. Cloud orchestration module 641 manages the transfer and storage of images, deploys new instantiations of VCEs and manages active instantiations of VCE deployments. Gateway 640 is the collection of computer software, hardware, and firmware that allows public cloud 605 to communicate through WAN 602. Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 606 is similar to public cloud 605, except that the computing resources are only available for use by a single enterprise. While private cloud 606 is depicted as being in communication with WAN 602, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 605 and private cloud 606 are both part of a larger hybrid cloud.

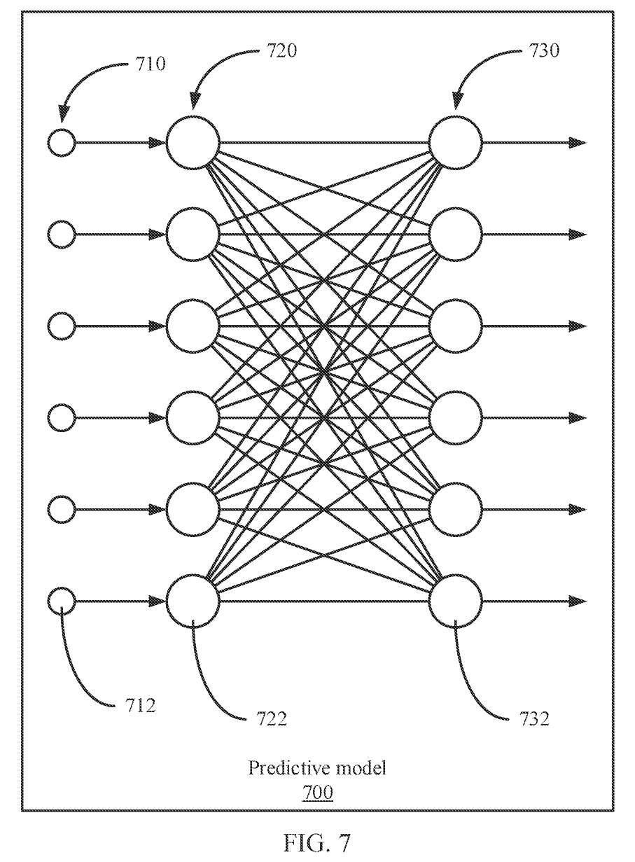

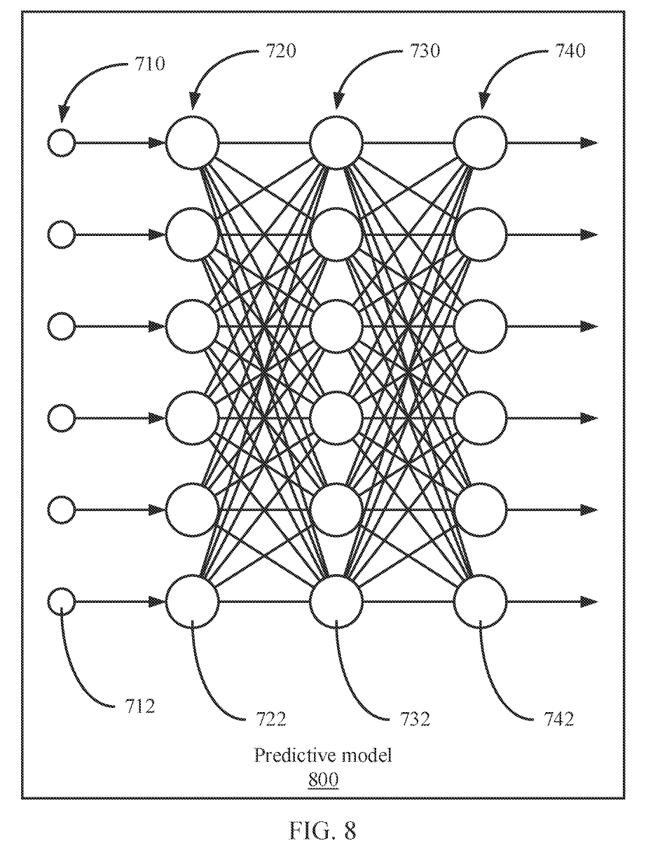

Referring now to FIGS. 7 and 8, exemplary neural network architectures are shown, which may be used to implement parts of the present models, such as predictive model 700/800. A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the inputted data belongs to each of the classes can be outputted.

The empirical data, also known as training data, from a set of examples can be formatted as a string of values and fed into the input of the neural network. Each example may be associated with a known result or output. Each example can be represented as a pair, (x, y), where x represents the input data and y represents the known output. The input data may include a variety of different data types, and may include multiple distinct values. The network can have one input node for each value making up the example’s input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples, and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. An exemplary simple neural network has an input layer 720 of source nodes 722, and a single computation layer 730 having one or more computation nodes 732 that also act as output nodes, where there is a single computation node 732 for each possible category into which the input example could be classified. An input layer 720 can have a number of source nodes 722 equal to the number of data values 712 in the input data 710. The data values 712 in the input data 710 can be represented as a column vector. Each computation node 732 in the computation layer 730 generates a linear combination of weighted values from the input data 710 fed into input nodes 720, and applies a non-linear activation function that is differentiable to the sum. The exemplary simple neural network can perform classification on linearly separable examples (e.g., patterns).

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

A deep neural network, such as a multilayer perceptron, can have an input layer 720 of source nodes 722, one or more computation layer(s) 730 having one or more computation nodes 732, and an output layer 740, where there is a single output node 742 for each possible category into which the input example could be classified. An input layer 720 can have a number of source nodes 722 equal to the number of data values 712 in the input data 710. The computation nodes 732 in the computation layer(s) 730 can also be referred to as hidden layers, because they are between the source nodes 722 and output node(s) 742 and are not directly observed. Each node 732, 742 in a computation layer generates a linear combination of weighted values from the values output from the nodes in a previous layer, and applies a non-linear activation function that is differentiable over the range of the linear combination. The weights applied to the value from each previous node can be denoted, for example, by w₁, w₂, … w_{n-1,} wₙ. The output layer provides the overall response of the network to the inputted data. A deep neural network can be fully connected, where each node in a computational layer is connected to all other nodes in the previous layer, or may have other configurations of connections between layers. If links between nodes are missing, the network is referred to as partially connected.

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of interface modulation and button function replication (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer-implemented method for interface modulation, comprising:
recording interactions by a device operator with an original interface of the device;
interactions by a device operator with an original interface of the device;
a function of the original interface using a trained predictive model that receives sequences of the interactions;
a three-dimensional (3D) design for a new interface that includes an indicator of the function; and
a new interface according to the 3D design using an additive manufacturing process.

2. The method of claim 1, wherein generating the 3D design includes adding a symbol to a blank 3D design that corresponds with a structure of the original interface.

3. The method of claim 2, wherein the symbol is added as a raised or embossed structure on the blank 3D design.

4. The method of claim 2, further comprising generating the symbol using a generative adversarial network, based on the function.

5. The method of claim 2, further comprising looking the symbol up in a database based on a keyword corresponding to the function.

6. The method of claim 2, wherein the symbol is a representation of a number that indicates an order or priority of the function in a sequence.

7. The method of claim 1, wherein recording interactions by a device operator includes applying the interactions to a digital twin of the device.

8. The method of claim 7, further comprising wherein determining the function includes using an output of the digital twin responsive to the interactions.

9. The method of claim 1, wherein recording the interactions includes monitoring the device using a video camera.

10. The method of claim 1, further comprising replacing the original interface with the new interface.

11. A computer program product, comprising:
one or more computer-readable storage media; and
program instructions stored on the one or more storage media to perform operations comprising:
recording interactions by a device operator with an original interface of the device;
determining a function of the original interface using a trained predictive model that receives sequences of the interactions;
generating a three-dimensional (3D) design for a new interface that includes an indicator of the function; and
triggering fabrication of a new interface according to the 3D design using an additive manufacturing process.

12. A computer system, comprising:
a processor set;
one or more computer-readable storage media; and
program instructions stored on the one or more storage media to cause the processor set to perform operations comprising:
recording interactions by a device operator with an original interface of the device;
determining a function of the original interface using a trained predictive model that receives sequences of the interactions;
generating a three-dimensional (3D) design for a new interface that includes an indicator of the function; and
triggering fabrication of a new interface according to the 3D design using an additive manufacturing process.

13. The system of claim 12, wherein generating the 3D design includes adding a symbol to a blank 3D design that corresponds with a structure of the original interface.

14. The system of claim 13, wherein the symbol is added as a raised or embossed structure on the blank 3D design.

15. The system of claim 13, further comprising generating the symbol using a generative adversarial network, based on the function.

16. The system of claim 13, further comprising looking the symbol up in a database based on a keyword corresponding to the function.

17. The system of claim 13, wherein the symbol is a representation of a number that indicates an order or priority of the function in a sequence.

18. The system of claim 12, wherein recording interactions by a device operator includes applying the interactions to a digital twin of the device.

19. The system of claim 18, further comprising wherein determining the function includes using an output of the digital twin responsive to the interactions.

20. The system of claim 12, wherein recording the interactions includes monitoring the device using a video camera.
